(19) United States
(12) Patent Application Publication
(10) Pub. No.: US 2017/0076938 A1
(43) Pub. Date: Mar. 16, 2017

(54) SUBSTRATE PROCESSING METHOD, SUBSTRATE PROCESSING APPARATUS, AND STORAGE MEDIUM

(71) Applicant: Tokyo Electron Limited, Tokyo (JP)

(72) Inventor: Kazuyuki Mitsuoka, Fukuoka-shi (Fukuoka) (JP)

(21) Appl. No.: 15/260,504

(22) Filed: Sep. 9, 2016

(30) Foreign Application Priority Data
Sep. 15, 2015 (JP) 2015-182234

(51) Int. Cl. H01L 21/02; F26B 21/14; B08B 3/08

(52) U.S. Cl. CPC H01L 21/02057; B08B 3/08; F26B 21/14

(57) ABSTRACT

A substrate processing method including: conveying a workpiece with a puddle of a dry preventing liquid into a supercritical processing unit container; and supplying a supercritical processing fluid to an outside or a top side of the workpiece within the supercritical processing unit container, or a top side of the workpiece outside the supercritical processing unit container. The supercritical processing fluid in liquid state or a mixed liquid of the dry preventing liquid and the supercritical processing fluid is heated to be placed in a supercritical state in the supercritical processing unit container. The inside of the supercritical processing unit container is supplied with N₂ gas in advance and pressurized before the supercritical processing fluid in liquid state or the mixed liquid of the dry preventing liquid and the supercritical processing fluid is heated in the supercritical processing unit container.

### CROSS-REFERENCE TO RELATED APPLICATIONS

This application is based on and claims priority from Japanese Patent Application No. 2015-182234, filed on Sep. 15, 2015, with the Japan Patent Office, the disclosure of which is incorporated herein in its entirety by reference.

### TECHNICAL FIELD

The present disclosure relates to a substrate processing method and apparatus and a storage medium of removing a liquid attached to a front surface of a substrate using a fluid in a supercritical state.

### BACKGROUND

In a semiconductor device manufacturing process of forming a laminated structure of an integrated circuit on a front surface of, for example, a semiconductor wafer (hereinafter, referred to as a “wafer”) that is a substrate, there is provided a liquid processing step of processing a wafer surface using a liquid, that is, a step of removing minute dust or a natural oxide film on the wafer surface using a cleaning liquid such as, for example, a chemical liquid.

As a method of removing the liquid attached to the wafer surface, a method using a fluid in a supercritical state has been known.

For example, in Japanese Patent Laid-Open Publication 2014-22566, fluorine-containing organic solvents are used in both a dry preventing liquid and a fluid in a supercritical state in view of a high replacement property between a liquid and a fluid in a supercritical state, or a moisture entering suppression at the time of a liquid processing.

Meanwhile, there has been developed a supercritical processing technology of conveying a wafer with a puddle of a dry preventing liquid (e.g., FC43) into a supercritical processing unit container, supplying a supercritical processing liquid (e.g., FC72) having a lower boiling point than that of the dry preventing liquid into the supercritical processing unit container, and removing the dry preventing liquid by a supercritical processing fluid.

The inventors have found that when a processing using a supercritical processing fluid in a supercritical state is performed by supplying the supercritical processing fluid in a state of a liquid or a gas such as a vapor into a supercritical processing unit container, and heating the supercritical processing unit container, the dry preventing liquid on the wafer may be dried while the supercritical processing fluid is being placed in the supercritical state, and thus a pattern collapse may occur. Also, they found that after, for example, a supercritical processing fluid in liquid state is supplied to the top side of the wafer, and a mixed liquid of the dry preventing liquid and the supercritical processing fluid in liquid state is formed on the wafer, when the supercritical processing unit container is heated, the mixed liquid may be boiled, thereby causing a pattern collapse.

### SUMMARY

The present disclosure provides a substrate processing method including: conveying a workpiece with a puddle of a dry preventing liquid into a supercritical processing unit container; supplying a supercritical processing fluid having a lower boiling point than that of the dry preventing liquid to an outside or a top side of the workpiece within the supercritical processing unit container, or a top side of the workpiece outside the supercritical processing unit container; and forming a fluid in a supercritical state by heating the supercritical processing fluid or a mixed liquid of the dry preventing liquid and the supercritical processing fluid within the supercritical processing unit container. Before the forming the fluid in the supercritical state by heating the supercritical processing fluid or the mixed liquid of the dry preventing liquid and the supercritical processing fluid within the supercritical processing unit container, an inert gas is supplied into the supercritical processing unit container in advance so as to pressurize an inside of the supercritical processing unit container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional plan view of a liquid processing apparatus.

FIG. 2 is a vertical-sectional side view of a liquid processing unit provided in the liquid processing apparatus.

FIG. 3 is a block diagram of a supercritical processing unit provided in the liquid processing apparatus.

FIG. 4 is an external perspective view of a processing container of the supercritical processing unit.

FIG. 5 is a view illustrating an action of the present exemplary embodiment.

FIG. 6 is a view illustrating an action of the present exemplary embodiment

FIG. 7 is a view illustrating an action of the present exemplary embodiment

FIG. 8 is a view illustrating an action of the present exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made in consideration of the above circumstances, and an object thereof is to provide a substrate processing method and apparatus, and a storage medium of removing a liquid attached to a wafer surface by a supercritical processing while suppressing a pattern collapse on a wafer.

According to the present disclosure, a substrate processing method includes: conveying a workpiece with a puddle of a dry preventing liquid into a supercritical processing unit container; supplying a supercritical processing fluid having a lower boiling point than that of the dry preventing liquid to an outside or a top side of the workpiece within the supercritical processing unit container, or a top side of the workpiece outside the supercritical processing unit container; and forming a fluid in a supercritical state by heating the supercritical processing fluid or a mixed liquid of the dry preventing liquid and the supercritical processing fluid within the supercritical processing unit container. Before the forming the fluid in the supercritical state by heating the supercritical processing fluid or the mixed liquid of the dry preventing liquid and the supercritical processing fluid within the supercritical processing unit container, an inert gas is supplied into the supercritical processing unit container in advance so as to pressurize an inside of the supercritical processing unit container.

In the above described substrate processing method, the inert gas is supplied into the supercritical processing unit container before the supplying the supercritical processing fluid.

In the above described substrate processing method, the inert gas is supplied into the supercritical processing unit container simultaneously with or after the supplying the supercritical processing fluid.

In the above described substrate processing method, the inert gas is supplied into the supercritical processing unit container at a pressure in a range of atmospheric pressure to 1.0 MPa.

According to the present disclosure, a substrate processing apparatus includes: a conveyance unit configured to convey a workpiece with a puddle of a dry preventing liquid into a supercritical processing unit container; a supercritical processing fluid supply unit configured to supply a supercritical processing fluid having a lower boiling point than that of the dry preventing liquid to an outside or a top side of the workpiece within the supercritical processing unit container, or a top side of the workpiece outside the supercritical processing unit container; and a heating unit configured to form a fluid in a supercritical state by heating the supercritical processing fluid or a mixed liquid of the dry preventing liquid and the supercritical processing fluid within the supercritical processing unit container. The substrate processing apparatus is provided with an inert gas supply unit for the supercritical processing unit container which is configured to supply an inert gas into the supercritical processing unit container in advance so as to pressurize an inside of the supercritical processing unit container before the supercritical processing fluid or the mixed liquid of the dry preventing liquid and the supercritical processing fluid within the supercritical processing unit container is heated to form the fluid in the supercritical state.

According to the present disclosure, a non-transitory computer-readable storage medium that stores a computer program for performing a substrate processing method. The substrate processing method includes: conveying a workpiece with a puddle of a dry preventing liquid into a supercritical processing unit container; supplying a supercritical processing fluid having a lower boiling point than that of the dry preventing liquid to an outside or a top side of the workpiece within the supercritical processing unit container, or a top side of the workpiece outside the supercritical processing unit container; and forming a fluid in a supercritical state by heating the supercritical processing fluid or a mixed liquid of the dry preventing liquid and the supercritical processing fluid within the supercritical processing unit container. Before the forming the fluid in the supercritical state by heating the supercritical processing fluid or the mixed liquid of the dry preventing liquid and the supercritical processing fluid within the supercritical processing unit container, an inert gas is supplied into the supercritical processing unit container in advance so as to pressurize an inside of the supercritical processing unit container.

According to the present exemplary embodiment, a liquid attached to the front surface of the wafer may be removed by a supercritical processing without causing a pattern collapse.

### Substrate Processing Apparatus

First, a substrate processing apparatus according to the present disclosure will be described. As an example of the substrate processing apparatus, descriptions will be made on a liquid processing apparatus 1 including liquid processing units 2 configured to perform a liquid processing by supplying various processing liquids to a wafer W (a workpiece) that is a substrate, and supercritical processing units 3 into which wafers W attached with a dry preventing liquid after the liquid processing are conveyed and which perform a supercritical processing on the wafers W.

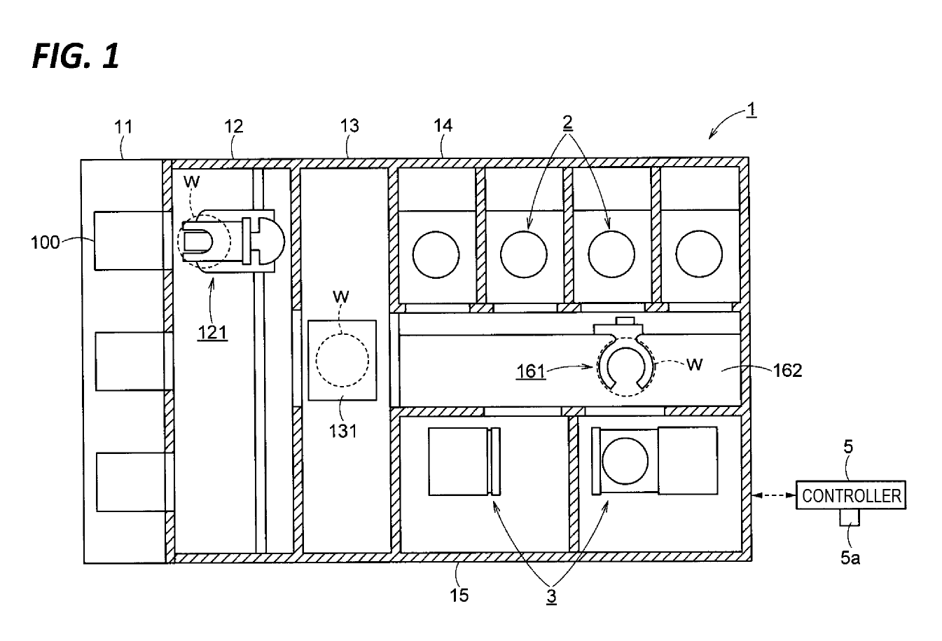

FIG. 1 is a cross-sectional plan view illustrating the whole configuration of the liquid processing apparatus 1, in which the left side in the drawing is assumed as the front side. In the liquid processing apparatus 1, front opening unified pods (FOUPs) 100 are placed on a placing section 11, and a plurality of wafers W with a diameter of, for example, 300 mm, housed in the FOUPs 100, are delivered between a liquid processing section 14 and a supercritical processing section 15 at the post stage through a carry-in/out section 12 and a delivery section 13, and carried into the liquid processing units 2 and the supercritical processing units 3 in sequence, so that a liquid processing or a processing of removing the dry preventing liquid is performed. In the drawing, reference numeral 121 denotes a first conveyance mechanism that conveys the wafers W between the FOUPs 100 and the delivery section 13, and reference numeral 131 is a delivery shelf that serves as a buffer on which the wafers W conveyed between the carry-in/out section 12, and the liquid processing section 14 and the supercritical processing section 15 are temporarily placed.

The liquid processing section 14 and the supercritical processing section 15 are provided across a conveyance space 162 of the wafers W that extends in the longitudinal direction from an opening between the conveyance space 162 and the delivery section 13. In the liquid processing section 14 provided on the left side of the conveyance space 162 in the front side view, for example, four liquid processing units 2 are arranged along the conveyance space 162. Meanwhile, in the supercritical processing section 15 provided on the right side of the conveyance space 162, for example, two supercritical processing units 3 are arranged along the conveyance space 162.

The wafers W are conveyed between each of the liquid processing units 2, each of the supercritical processing units 3, and the delivery section 13 by a second conveyance mechanism 161 disposed in the conveyance space 162. The second conveyance mechanism 161 corresponds to a substrate conveyance unit. Here, the number of the liquid processing units 2 or the supercritical processing units 3 disposed in the liquid processing section 14 or the supercritical processing section 15 is appropriately selected depending on, for example, the number of the wafers W processed per unit time, or the difference in processing time between the liquid processing units 2 and the supercritical processing units 3, and the optimal layout is selected depending on, for example, the number of the arranged liquid processing units 2 or supercritical processing units 3.

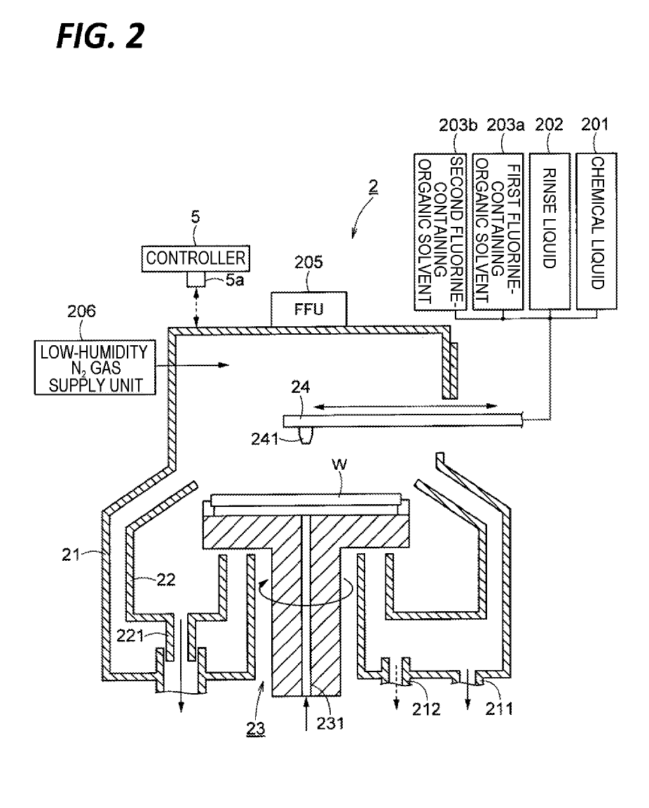

Each of the liquid processing units 2 is configured as a single wafer type liquid processing unit 2 that cleans the wafers W one by one by, for example, spin cleaning. As illustrated in the vertical-sectional side view of FIG. 2, the liquid processing unit 2 includes: an outer chamber 21 as a chamber for a liquid processing unit that defines a processing space; a wafer holding mechanism 23 disposed within the outer chamber and configured to rotate the wafer W around a vertical axis while holding the wafer W substantially horizontally; an inner cup 22 disposed to surround the wafer holding mechanism 23 from the lateral peripheral side thereof and configured to receive a liquid scattered from the wafer W; and a nozzle arm 24 configured to be movable between a position above the wafer W and a position retracted therefrom and provided with a nozzle 241 in the tip end portion thereof.

The nozzle 241 is connected with a processing liquid supply unit 201 that supplies various chemical liquids (such as, for example, DHF) or a DIW, a rinse liquid supply unit 202 that supplies a rinse liquid (IPA), and a first fluorine-containing organic solvent supply unit 203a and a second fluorine-containing organic solvent supply unit 203b that supply a first fluorine-containing organic solvent and a second fluorine-containing organic solvent, respectively, as dry preventing liquids to the front surface of the wafer W. As the first fluorine-containing organic solvent and the second fluorine-containing organic solvent, ones those are different from a supercritical processing fluorine-containing organic solvent used in a supercritical processing to be described below are used. Further, as the first fluorine-containing organic solvent, the second fluorine-containing organic solvent, and the supercritical processing fluorine-containing organic solvent, solvents having a predetermined relationship in a boiling point or a critical temperature are adopted, but details thereof sill be described below.

A fan filter unit (FFU) 205 is provided in the outer chamber 21, and cleaned air is supplied from the FFU 205 into the outer chamber 21. Further, a low-humidity N₂ gas supply unit 206 is provided in the outer chamber 21, and a low-humidity N₂ gas is supplied from the low-humidity N₂ gas supply unit 206 into the outer chamber 21.

A chemical liquid supply path 231 may be formed inside the wafer holding mechanism 23, so that a rear surface cleaning of the wafer W may be performed by a chemical liquid and a rinse liquid supplied therefrom. In the bottom portion of the outer chamber 21 or the inner cup 22, an exhaust port 212 configured to exhaust the internal atmosphere, or a drain port 221, 211 configured to discharge the liquid splashing from the wafer W is provided.

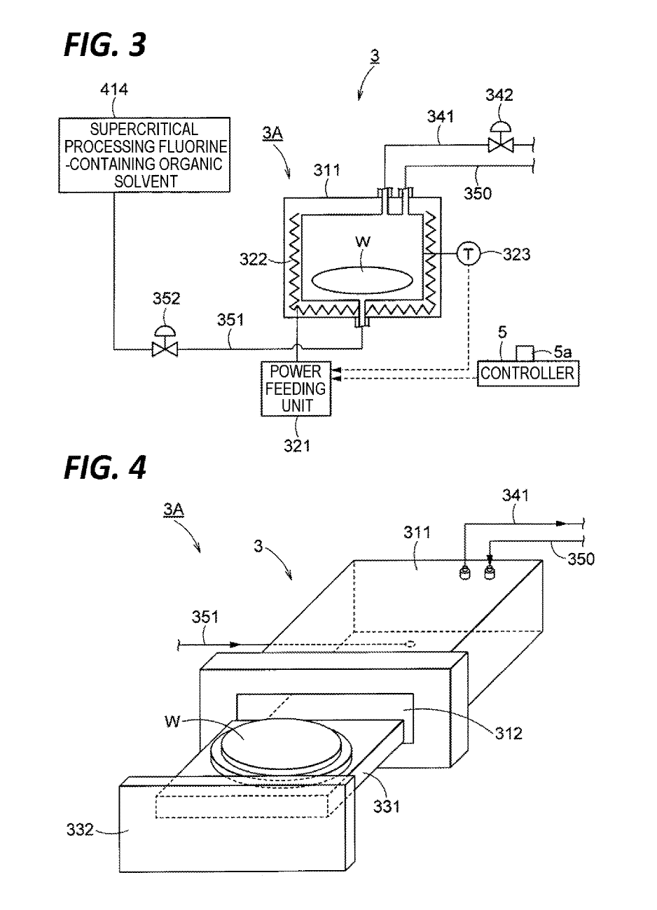

The first fluorine-containing organic solvent and the second fluorine-containing organic solvent which become dry preventing liquids are supplied to the wafer W that has been subjected to the liquid processing in the liquid processing unit 2. The wafer W, in a state where its front surface is covered with the liquid of the second fluorine-containing organic solvent, is conveyed to the supercritical processing unit 3 by the second conveyance mechanism 161. In the supercritical processing unit 3, a supercritical processing is performed in which the wafer W is brought into contact with the supercritical processing fluid of the supercritical processing fluorine-containing organic solvent so that the liquid of the second fluorine-containing organic solvent is removed and the wafer W is dried. Hereinafter, the configuration of the supercritical processing unit 3 will be described with reference to FIGS. 3 and 4.

The supercritical processing unit 3 includes a processing container 3A serving as a supercritical processing unit container where a processing of removing the liquid of the second fluorine-containing organic solvent attached to the front surface of the wafer W is performed, and a supercritical processing fluid supply unit 414 configured to supply the supercritical processing fluorine-containing organic solvent to the processing container 3A.

As illustrated in FIG. 4, the processing container 3A includes a casing-type container body 311 having an opening 312 for carry-in/out of the wafer W formed therein, a wafer tray 331 capable of horizontally holding the wafer W, which is a processing target, and a cover member 332 configured to support the wafer tray 331 and seal the opening 312 when the wafer W is carried into the container body 311.

The container body 311 is, for example, a container in which a processing space with a volume of about 200 cm³ to 10,000 cm³ which is capable of accommodating the wafer W having a diameter of 300 mm, is formed. A supercritical processing fluid supply line 351 configured to supply the supercritical processing fluid into the processing container 3A is connected to the bottom side of the container body 311, and a discharge line 341 (a discharge unit) interposed with an opening/closing valve 342 and configured to discharge the fluid within the processing container 3A is connected to the top side of the container body 311. The processing container 3A is provided with a pressing mechanism (not illustrated) configured to seal the processing space by pressing the cover member 332 toward the container body 311 against an internal pressure applied from a processing fluid in a supercritical state within the processing space. An inert gas supply unit 350 for the supercritical processing unit container is provided at the top side of the container body 311. The inert gas supply unit 350 for the supercritical processing unit container is configured to supply an inert gas into the container body 311 so that the inside of the container body 311 is pressurized before the supercritical processing fluid within the container body 311 is heated by a heater 322 to be described below and thus is placed in a supercritical state.

The container body 311 is provided with the heater 322 which is a heating unit constituted by, for example, a resistance heating element, and a temperature detecting unit 323 including, for example, a thermocouple for detecting a temperature within the processing container 3A. The temperature within the processing container 3A may be raised to a predetermined temperature by heating the container body 311, and thus the wafer W within the processing container 3A may be heated. The heater 322 may change a caloric value by changing a power supplied from a power feeding unit 321, and control the temperature within the processing container 3A to a predetermined temperature based on the temperature detection result acquired from the temperature detecting unit 323.

The supercritical processing fluid supply unit 414 is connected to the upstream side of the supercritical processing fluid supply line 351 interposed with an opening/closing valve 352. The supercritical processing fluid supply unit 414 is configured to supply a liquid of the supercritical processing fluorine-containing organic solvent.

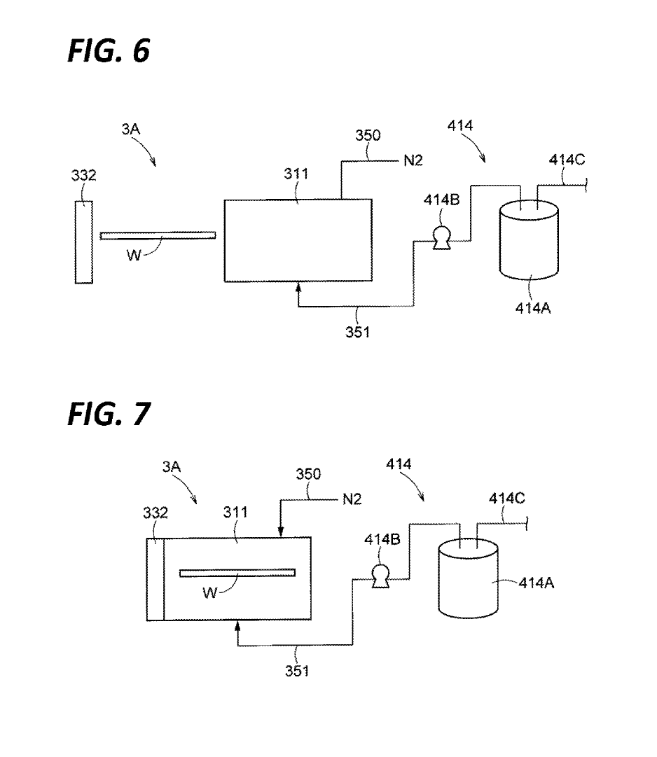

The supercritical processing fluid supply unit 414 includes, for example, a tank 414A that stores the supercritical processing fluorine-containing organic solvent in a liquid state, a liquid-feeding high-pressure pump 414B, a N₂ gas supply line 414C, and a flow control mechanism (see FIGS. 6 to 8).

The liquid processing apparatus 1 including the liquid processing unit 2 or the supercritical processing unit 3 configured as described above is connected to a controller 5 as illustrated in FIGS. 1 to 3. The controller 5 is constituted by a computer including a CPU (not illustrated) and a storage unit 5a. The storage unit 5a stores a program that incorporates a group of steps (commands) on a control associated with operations of the liquid processing apparatus 1, that is, operations including taking the wafer W out from the FOUP 100, performing the liquid processing of the taken wafer W in the liquid processing unit 2, subsequently, drying the wafer W in the supercritical processing unit 3, and then, carrying the wafer W into the FOUP 100. The program is stored in a storage medium such as, for example, a hard disk, a compact disk, a magneto optical disk, or a memory card, and installed into the computer therefrom.

Next, descriptions will be made on the first fluorine-containing organic solvent and the second fluorine-containing organic solvent as dry preventing liquids supplied to the front surface of the wafer W by the liquid processing unit 2, and the supercritical processing fluorine-containing organic solvent supplied to the processing container 3A in order to remove the dry preventing liquid from the front surface of the wafer W. Here, all the first fluorine-containing organic solvent and the second fluorine-containing organic solvent as the dry preventing liquids, and the supercritical processing fluorine-containing organic solvent are fluorine-containing organic solvents that contain fluorine atoms in hydrocarbon molecules.

When among the fluorine-containing organic solvents, one fluorine-containing organic solvent is selected as the supercritical processing fluorine-containing organic solvent, one solvent having a higher boiling point (lower vapor pressure) than that of the supercritical processing fluorine-containing organic solvent is selected as the second fluorine-containing organic solvent. Therefore, the amount of the fluorine-containing organic solvent volatilized from the front surface of the wafer W may be reduced while the wafer W is conveyed from the liquid processing unit 2 to the supercritical processing unit 3, as compared with a case in which the supercritical processing fluorine-containing organic solvent is adopted as the dry preventing liquid.

More preferably, the boiling point of the first fluorine-containing organic solvent may be around 100° C., and the boiling point of the second fluorine-containing organic solvent may be higher than the boiling point of the first fluorine-containing organic solvent, i.e., 100° C. or more. Since the second fluorine-containing organic solvent having a boiling point of 100° C. or more is smaller in volatilization amount during the conveyance of the wafer W, the front surface of the wafer W may be maintained in a wet state for several tens of seconds to about 10 minutes only by supplying a small amount of fluorine-containing organic solvent, that is, in an amount of about 0.01 cc to 5 cc to a wafer W with a diameter 300 mm, or in an amount of about 0.02 cc to 10 cc to a wafer W with a diameter of 450 mm For reference, IPA needs to be supplied in an amount of about 10 cc to 50 cc to maintain the front surface of the wafer W in the wet state for the same time as above.

When the supercritical processing fluorine-containing organic solvent and the second fluorine-containing organic solvent are selected, a high and low level of the boiling point corresponds to a high and low level of a supercritical temperature. Therefore, when a solvent having a lower boiling point than that of the second fluorine-containing organic solvent is selected as for the supercritical processing fluorine-containing organic solvent to be used as the supercritical processing fluid, a fluorine-containing organic solvent capable of forming a supercritical fluid at a low temperature may be used, and the fluorine atoms may be suppressed from being released due to decomposition of the fluorine-containing organic solvent.

### Action of Present Exemplary Embodiment

Hereinafter, descriptions will be made on the action of the present exemplary embodiment configured as described above with reference to FIG. 1 to FIG. 8.

Following descriptions will be made on an action according to the present exemplary embodiment, in which dry preventing liquids including, for example, HFE7300 (Sumitomo 3M Kabushiki Kaisha Novec (registered trademark) 7300, boiling point: 98° C.) as a first fluorine-containing organic solvent, and, for example, FC43 (Sumitomo 3M Kabushiki Kaisha Fluorinert (registered trademark) FC-43, boiling point: 174° C.) as a second fluorine-containing organic solvent, and a supercritical processing fluid in liquid state including FC72 (Sumitomo 3M Kabushiki Kaisha Fluorinert (registered trademark) FC-72, boiling point: 56° C.), as a supercritical processing fluorine-containing organic solvent are used.

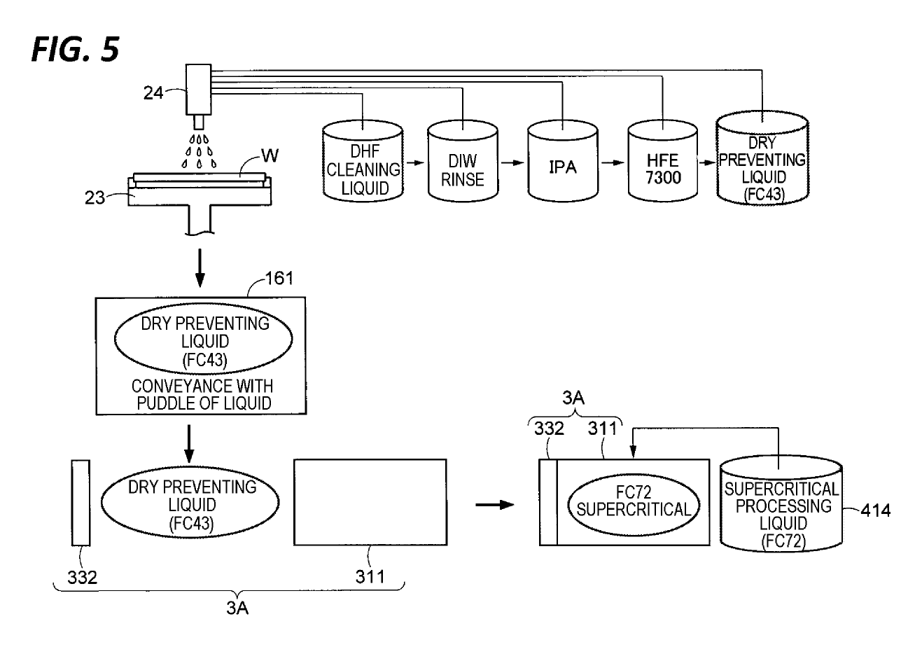

First, the wafer W taken out from the FOUP 100 is carried into the outer chamber 21 of the liquid processing section 14 through the carry-in/out section 12 and the delivery section 13, and delivered to the wafer holding mechanism 23 of the liquid processing unit 2. Then, various processing liquids are supplied to the front surface of the wafer W which is being rotated so that the liquid processing is performed (see FIG. 5).

In the liquid processing, particles or organic pollutant substances are removed by a chemical liquid supplied from the processing liquid supply unit 201, e.g., diluted hydrofluoric acid (DHF) which is an acidic chemical liquid, and a DIW cleaning is performed by deionized water (DIW) which is a rinse liquid supplied from the processing liquid supply unit 201.

When the liquid processing by the chemical liquid or the DIW cleaning is completed, IPA is supplied to the front surface of the rotating wafer W from the rinse liquid supply unit 202 (IPA supply unit) so as to substitute the DIW remaining on the front surface of the wafer W with the IPA. When the liquid on the front surface of the wafer W is sufficiently substituted with the IPA, the first fluorine-containing organic solvent (HFE7300) is supplied to the front surface of the rotating wafer W from the first fluorine-containing organic solvent supply unit 203a, and then the wafer W is continuously rotated. Then, the second fluorine-containing organic solvent containing FC43 as a dry preventing liquid is supplied to the front surface of the rotating wafer W from the second fluorine-containing organic solvent supply unit 203b, and then the rotation of the wafer W is stopped. After the rotation is stopped, the wafer W is placed in the state where its front surface is covered with the second fluorine-containing organic solvent containing FC43. In this case, since the IPA has high solubility with the DIW and HFE7300, the DIW may be substituted by the IPA, and then the IPA may be substituted by the HFE7300. Next, the HFE7300 may be substituted by the second fluorine-containing organic solvent containing FC43 as the dry preventing liquid.

Meantime, during the supply of the DHF, during the supply of the DIW, during the supply of the IPA, during the supply of the first fluorine-containing organic solvent, and during the supply of the second fluorine-containing organic solvent, a low humidity (with a dew point of −70° C. or less) N₂ gas is continuously supplied into the outer chamber 21 from the low-humidity N₂ gas supply unit 206 so that the inside of the outer chamber 21 is maintained at the low-humidity N₂ gas atmosphere. At this time, the humidity within the outer chamber 21 may be 3% or less.

In the exemplary embodiment as above, descriptions have been made on an example in which a low humidity N₂ gas is continuously supplied into the outer chamber 21 from the low-humidity N₂ gas supply unit 206 during the supply of the DHF, during the supply of the DIW, during the supply of the IPA, during the supply of the first fluorine-containing organic solvent, and during the supply of the second fluorine-containing organic solvent. However, without being limited to this, during the supply of the DHF, during the supply of the DIW, during the supply of the first fluorine-containing organic solvent, and during the supply of the second fluorine-containing organic solvent, purified air may be supplied into the outer chamber 21 from the FFU 205 by controlling the FFU 205 by the controller 5 while only during the supply of the IPA, the low-humidity N₂ gas may be supplied into the outer chamber 21 from the low-humidity N₂ gas supply unit 206 by controlling the low-humidity N₂ gas supply unit 206 by the controller 5. Alternatively, during the supply of the IPA and during the supply of the first fluorine-containing organic solvent, or during the supply of the IPA, during the supply of the first fluorine-containing organic solvent and during the supply of the second fluorine-containing organic solvent, the low-humidity N₂ gas may be supplied into the outer chamber 21 from the low-humidity N₂ gas supply unit 206 by controlling the low-humidity N₂ gas supply unit 206 by the controller 5. Accordingly, the use amount of the low-humidity N₂ gas supplied into the outer chamber 21 may be reduced.

Since the inside of the outer chamber 21 is maintained at a low-humidity N₂ gas atmosphere as described above, moisture absorption in the IPA may be suppressed, and thus a pattern collapse in the wafer W may be suppressed during a supercritical processing as described below.

The wafer W on which the liquid processings have been completed as described above is taken out of the liquid processing unit 2 by the second conveyance mechanism 161, and is conveyed to the supercritical processing unit 3. Here, the dry preventing liquid remains in a puddle state on the wafer W. The dry preventing liquid includes the second fluorine-containing organic solvent having a high boiling point (a low vapor pressure), e.g., FC43. Thus, the amount of the second fluorine-containing organic solvent volatilized from the front surface of the wafer W may be reduced while the wafer W is conveyed, thereby suppressing the top surface of the wafer W from being dried.

Then, as illustrated in FIGS. 3 and 4, when the wafer W is carried into the processing container 3A, the cover member 332 is closed such that the inside of the processing container 3A is placed in a sealed state.

Hereinafter, detailed descriptions will be made on a supercritical processing within the supercritical processing unit 3 with reference to FIGS. 5 to 8.

As illustrated in FIGS. 6 to 8, the supercritical processing fluid supply unit 414 includes the tank 414A that stores FC72, the liquid-feeding high-pressure pump 414B, and the N₂ gas supply line 414C.

First, as illustrated in FIGS. 5 and 6, the wafer W is conveyed into the processing container 3A, and the cover member 332 is closed with respect to the container body 311. The inside of the processing container 3A is heated to, for example, 200° C. by the operation of the heater 322.

Then, an inert gas such as, for example, N₂ gas, is supplied from the inert gas supply unit 350 for the supercritical processing unit container into the processing container 3A, and the inside of the processing container 3A is pressurized (see FIG. 7).

In this case, N₂ gas having a pressure in a range of atmospheric pressure to 1.0 MPa, e.g., N₂ gas having a pressure of 0.5 Mpa, is supplied from the inert gas supply unit 350 for the supercritical processing unit container. Thus, the inside of the processing container 3A is pressurized. The supply of the N₂ gas is stopped when, for example, the pressure within the processing container 3A reaches a range of 0.05 MPa to 0.5 MPa. The supply stop of the N₂ gas may not be based on the pressure, but the supply of N₂ gas may be stopped after a predetermined time of, for example, 1 sec to 30 sec from the supply start. Especially, when both the supercritical processing fluid and the N₂ gas are simultaneously supplied into the processing container 3A, such a control may be made based on the supply time.

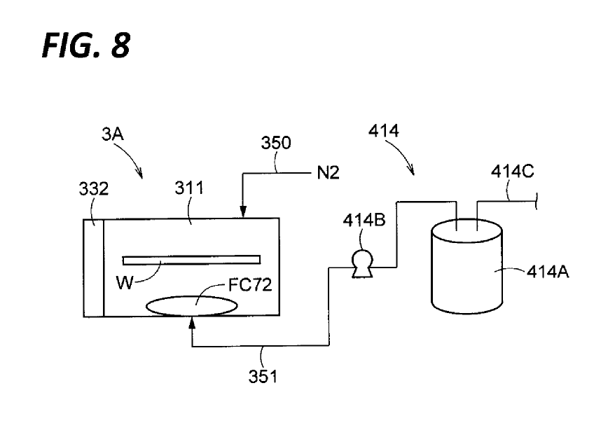

Then, as illustrated in FIG. 8, N₂ gas having a pressure of 0.1 MPa is supplied from the N₂ gas supply line 414C into the tank 414A. Here, the opening/closing valve 352 is opened, thereby discharging the FC72 within the tank 414A from the tank 414A. Then, the FC72 is boosted by the liquid-feeding high-pressure pump 414B of the supercritical processing fluid supply line 351 and supplied into the processing container 3A.

In this case, FC72 in liquid state supplied from the supercritical processing fluid supply line 351 is fed into the container body 311 through the bottom side of the container body 311.

After the supercritical processing fluid in liquid state is supplied from the supercritical processing fluid supply unit 414, the opening/closing valve 352 of the supercritical processing fluid supply line 351 is closed. The supercritical processing fluid (FC72) may be heated within the processing container 3A by the heater 322, and the inside of the processing container 3A may be pressurized so that the supercritical processing fluid (FC72) may be placed in a supercritical state.

In this case, within the processing container 3A, a dry preventing liquid (FC43) remains in a puddle state on the wafer W.

The inside of the processing container 3A is pressurized by N₂ gas supplied from the inert gas supply unit 350 for the supercritical processing unit container. This suppresses the FC43 on the wafer W from being rapidly evaporated, and thus the top of the wafer W is not rapidly dried and a pattern collapse does not occur.

That is, before the supercritical processing fluid (FC72) in liquid state within the processing container 3A is heated to be placed in a supercritical state, a rise in the internal pressure within the processing container 3A is small. Thus, when the inside of the processing container 3A is not pressurized by the N₂ gas, it may be expected that the FC43 on the wafer W is rapidly evaporated within the processing container 3A before the supercritical processing fluid (FC72) in liquid state within the processing container 3A is heated to be placed in the supercritical state.

On the contrary, according to the present exemplary embodiment, the supercritical processing fluid in liquid state within the processing container 3A is heated to be placed in a supercritical state after the inside of the processing container 3A is pressurized by the N₂ gas. Thus, the FC43 on the wafer W is suppressed from being rapidly evaporated, and thus the wafer W is not dried and a pattern collapse does not occur.

Then, after the lapse of time required to remove the dry preventing liquid from the front surface of the wafer W, the opening/closing valve 342 of the discharge line 341 is opened to discharge the supercritical processing fluid in a supercritical state or in gas from the inside of the processing container 3A. Here, the inside of the processing container 3A is maintained at a temperature equal to or higher than, for example, a critical temperature of a mixed liquid by the heater 322. As a result, the supercritical processing fluid may be discharged in a supercritical state or a gas state without liquefying the dry preventing liquid, and an occurrence of a pattern collapse may be avoided during the fluid discharge.

When the processing with the supercritical fluid is completed, the wafer W, which has been dried by removing the liquid, is taken out by the second conveyance mechanism 161, and housed in the FOUP 100 through the delivery section 13 and the carry-in/out section 12. Then, a series of processings on the wafer W is completed. In the liquid processing apparatus 1, the above-described processings are sequentially performed on respective wafers W within the FOUPs 100.

According to the present exemplary embodiment as described above, since the supercritical processing fluid within the processing container 3A is heated to be placed in a supercritical state after the inside of the processing container 3A is pressurized by the N₂ gas. The FC43 on the wafer W is not rapidly evaporated, and a pattern collapse does not occur.

### Modification of the Present Disclosure

In the exemplary embodiment as above, descriptions have been made on an exemplary case where after N₂ gas is supplied into the processing container 3A from the inert gas supply unit 350 for the supercritical processing unit container, a supercritical processing fluid is supplied into the processing container 3A from the supercritical processing fluid supply unit 414, but the present disclosure is not limited thereto. Both the N₂ gas and the supercritical processing fluid may be simultaneously supplied into the processing container 3A, or N₂ gas may be supplied after the supercritical processing fluid is supplied into the processing container 3A.

Alternatively, the N₂ gas supplied into the processing container 3A may have a pressure in a range of atmospheric pressure to 1.0 MPa.

In the present exemplary embodiment, descriptions have been made on an exemplary method in which the wafer W is introduced into the processing container 3A and the FC72 in liquid state supplied from the supercritical processing fluid supply line 351 is fed into the container body 311 through the bottom side of the container body 311, but the present disclosure is not limited thereto. The FC72 in liquid state may be supplied to the top side of the wafer W covered with the FC43 at the outside of the processing container 3A such that the wafer W covered with a mixed liquid of FC43 and FC72 may be introduced into the processing container 3A, and then N₂ gas may be supplied into the processing container 3A before the mixed liquid on the wafer W is placed in a supercritical state. Otherwise, FC72 in liquid state may be supplied to the top side of the wafer W covered with FC43 within the processing container 3A, thereby producing a mixed liquid of FC43 and FC72, and then N₂ gas may be supplied into the processing container 3A before the mixed liquid on the wafer W is placed in a supercritical state. Accordingly, even when a mixed liquid of the dry preventing liquid and the supercritical processing fluid in liquid state, which is formed on the wafer, is heated, the mixed liquid is suppressed from being boiled so that an occurrence of a pattern collapse may be suppressed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
conveying a workpiece with a puddle of a dry preventing liquid into a supercritical processing unit container;
supplying a supercritical processing fluid having a lower boiling point than that of the dry preventing liquid to an outside or a top side of the workpiece within the supercritical processing unit container, or a top side of the workpiece outside the supercritical processing unit container; and
forming a fluid in a supercritical state by heating the supercritical processing fluid or a mixed liquid of the dry preventing liquid and the supercritical processing fluid within the supercritical processing unit container,
wherein before the forming the fluid in the supercritical state by heating the supercritical processing fluid or the mixed liquid of the dry preventing liquid and the supercritical processing fluid within the supercritical processing unit container, an inert gas is supplied into the supercritical processing unit container in advance so as to pressurize an inside of the supercritical processing unit container.

2. The substrate processing method of claim 1, wherein the inert gas is supplied into the supercritical processing unit container before the supplying the supercritical processing fluid.

3. The substrate processing method of claim 1, wherein the inert gas is supplied into the supercritical processing unit container simultaneously with or after the supplying the supercritical processing fluid.

4. The substrate processing method of claim 1, wherein the inert gas is supplied into the supercritical processing unit container at a pressure in a range of atmospheric pressure to 1.0 MPa.

5. A substrate processing apparatus comprising:
a conveyance unit configured to convey a workpiece with a puddle of a dry preventing liquid into a supercritical processing unit container;
a supercritical processing fluid supply unit configured to supply a supercritical processing fluid having a lower boiling point than that of the dry preventing liquid to an outside or a top side of the workpiece within the supercritical processing unit container, or a top side of the workpiece outside the supercritical processing unit container; and
a heating unit configured to form a fluid in a supercritical state by heating the supercritical processing fluid or a mixed liquid of the dry preventing liquid and the supercritical processing fluid within the supercritical processing unit container,
wherein the substrate processing apparatus is provided with an inert gas supply unit for the supercritical processing unit container which is configured to supply an inert gas into the supercritical processing unit container in advance so as to pressurize an inside of the supercritical processing unit container before the supercritical processing fluid or the mixed liquid of the dry preventing liquid and the supercritical processing fluid within the supercritical processing unit container is heated to form the fluid in the supercritical state.

6. A non-transitory computer-readable storage medium that stores a computer program for performing a substrate processing method,
wherein the substrate processing method includes:
conveying a workpiece with a puddle of a dry preventing liquid into a supercritical processing unit container;
supplying a supercritical processing fluid having a lower boiling point than that of the dry preventing liquid to an outside or a top side of the workpiece within the supercritical processing unit container, or a top side of the workpiece outside the supercritical processing unit container; and
forming a fluid in a supercritical state by heating the supercritical processing fluid or a mixed liquid of the dry preventing liquid and the supercritical processing fluid within the supercritical processing unit container,
wherein before the forming the fluid in the supercritical state by heating the supercritical processing fluid or the mixed liquid of the dry preventing liquid and the supercritical processing fluid within the supercritical processing unit container, an inert gas is supplied into the supercritical processing unit container in advance so as to pressurize an inside of the supercritical processing unit container.
